(19) United States
(12) Patent Application Publication
(10) Pub. No.: US 2012/0268335 A1
(43) Pub. Date: Oct. 25, 2012

(54) ANTENNA AND METHOD OF MAKING SAME

(75) Inventors: XUE-LI ZHANG, Shenzhen City (CN); YONG YAN, Shenzhen City (CN); YONG-FA FAN, Shenzhen City (CN); ZHAO-YI WU, Shenzhen City (CN); QI-YUAN LI, Shenzhen City (CN); LI LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/277,462

(22) Filed: Oct. 20, 2011

(30) Foreign Application Priority Data
Apr. 22, 2011 (CN) 201110101838.6

(51) Int. Cl. H01Q 1/00; C25D 5/02; C25D 7/00; C23C 14/14

(52) U.S. Cl. 343/787; 427/597; 205/122

(57) ABSTRACT

An antenna includes a base body, an antenna radiator and a ferrite core. The base body includes a laser direct structuring material. The antenna radiator is formed by selectively activating a portion of the base body with a laser and by plating the activated portion. The ferrite core is fixed to the antenna radiator.

### CROSS-REFERENCE TO RELATED APPLICATIONS

The present application is related to one co-pending U.S. patent application (Attorney Docket No. US39658), each entitled “ANTENNA AND METHOD OF MAKING SAME”, by Zhang et al. These applications have the same assignee as the present application and have been concurrently filed herewith. The above-identified applications are incorporated herein by reference.

### BACKGROUND

1. Technical Field

The disclosure generally relates to antennas and a method of making the antennas.

2. Description of the Related Art

Electronic devices (e.g. mobile phone) may include a printed circuit board (PCB), and a near field communication (NFC) antenna and a ferrite core mounted on the PCB. However, this assembly takes up too much interior space of the electronic device.

Therefore, there is room for improvement within the art.

### BRIEF DESCRIPTION OF THE DRAWINGS

Many aspects of the exemplary antenna and method of making the antenna can be better understood with reference to the following drawings. The components in the various drawings are not necessarily drawn to scale, the emphasis instead being placed upon clearly illustrating the principles of the exemplary antenna and method of making the antenna. Moreover, in the drawings, like reference numerals designate corresponding parts throughout the diagrams.

FIG. 1 is an assembled view of an exemplary antenna.

FIG. 2 is an exploded view of the antenna shown in FIG. 1.

### DETAILED DESCRIPTION

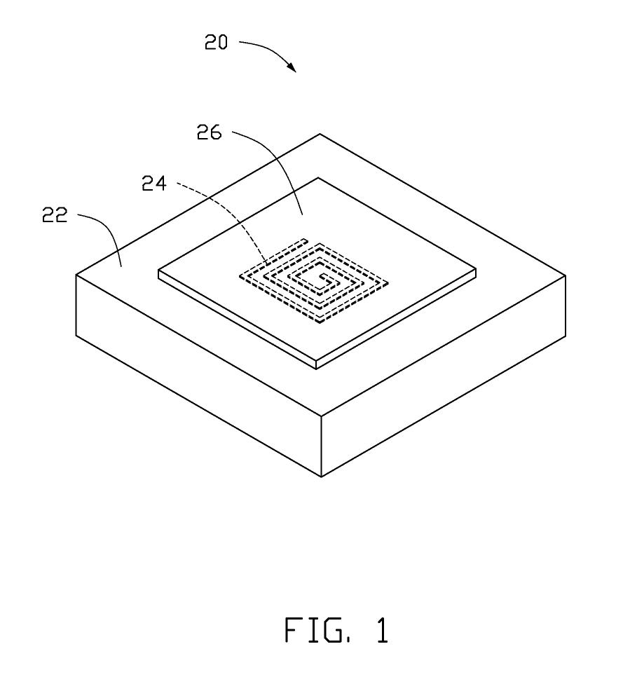

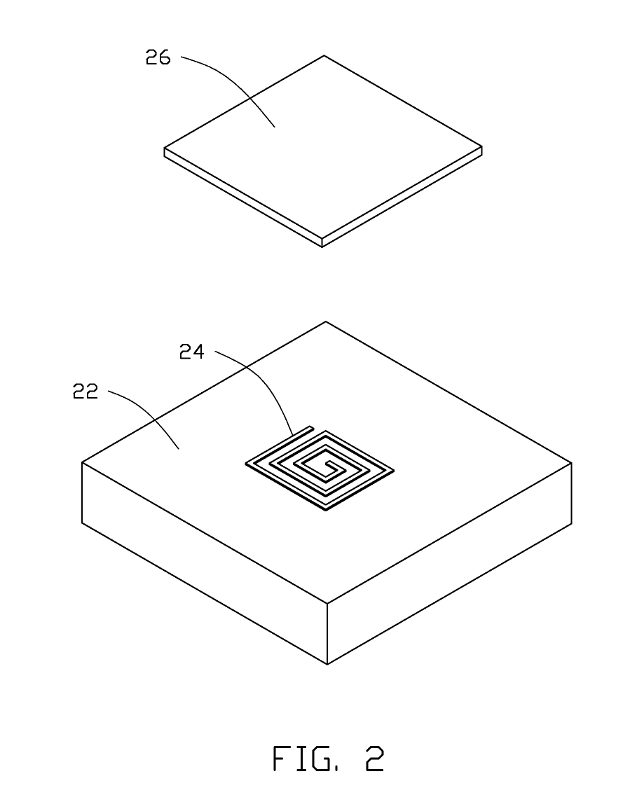

FIG. 1 and FIG. 2 show an exemplary antenna 20 including a base body 22, an antenna radiator 24 and a ferrite core 26. The antenna radiator 24 may be formed on the base body 22 by laser direct structuring (LDS). The ferrite core 26 is fixed to the antenna radiator 24.

The base body 22 can be formed by injecting molding. The base body 22 may be mixture of materials consisting of thermoplastic, organic filling substances, and laser direct structuring material. The thermoplastic can be polyvinyl chloride, polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, polypropylene, or any combination thereof. The base body 22, according to an exemplary embodiment, is polycarbonate. The organic filling substances can be silicic acid and/or silicic acid derivatives. The laser direct structuring material can be non-conductive spinel-based inorganic oxide, such as spinel type copper. The non-conductive oxide can be activated by laser to precipitate metallic crystal nuclei covering the base body 22.

The antenna radiator 24 is a plating layer formed on the base body 22. The antenna radiator 24 may be formed by selectively activating a portion of the base body 22 with a laser and plating the activated portion.

An exemplary embodiment of a method for making the antenna may include the following steps:

An injection molding machine is provided. The injection molding machine includes a molding chamber. The mixture is injected into the molding chamber to form the base body 22. A portion of the base body 22 is activated with a laser. The non-conductive oxide of the portion of the base body 22 is activated by the laser to precipitate metallic crystal nuclei covering the metal area of the base body 22. Thus, the metal area is conductive.

The metal area is metalized to form the antenna radiator 24 using a plating process. The plating process can be an electro-plating or a chemical plating method to form the plating layer.

The ferrite core 26 is adhered to the antenna radiator 24 thus the ferrite core 26 can cover the antenna radiator 24.

By including the antenna radiator 24 and the ferrite core 26, the antenna 20 can act as a near field communication (NFC) antenna. Additionally, the base body 22 can be molded with a corresponding shape to be conveniently assembled to the electronic device.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An antenna, comprising:
a base body, the base body comprising a laser direct structuring material;
an antenna radiator formed by selectively activating a portion of the base body with a laser and by plating the activated portion; and
a ferrite core covering the antenna radiator.

2. The antenna as claimed in claim 1, wherein the base body further comprises thermoplastic and organic filling substances.

3. The antenna as claimed in claim 2, wherein the thermoplastic is polyvinyl chloride, polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, polypropylene, or any combination thereof.

4. The antenna as claimed in claim 2, wherein the organic filling substances comprise silicic acid and/or silicic acid derivatives.

5. The antenna as claimed in claim 1, wherein the laser direct structuring material is spinel-based inorganic oxide.

6. The antenna as claimed in claim 5, wherein the laser direct structuring material is spinel copper.

7. The antenna as claimed in claim 1, wherein the laser direct structuring material is activated by laser to form a metal area, the metal area electroplated to form the antenna radiator.

8. The antenna as claimed in claim 1, wherein the ferrite core is adhered on the antenna radiator.

9. A method for making an antenna, comprising:
providing an injection molding machine comprising a molding chamber;
injecting a mixture selected from a group consisting of thermoplastic, organic filling substances, and laser direct structuring material into the molding chamber to form a base body;
selectively activating a portion of the base body with a laser;
plating the activated portion to from an antenna radiator; and
covering a ferrite core on the antenna radiator.

10. The method for making an antenna as claimed in claim 9, wherein the thermoplastic is polyvinyl chloride, polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, polypropylene, or any combination.

11. The method for making an antenna as claimed in claim 9, wherein the laser direct structuring material is spinel-based inorganic oxide.

12. The method for making an antenna as claimed in claim 11, wherein the laser direct structuring material is spinel copper.

13. The method for making an antenna as claimed in claim 9, wherein the laser direct structuring material is activated by laser to form a metal area, the metal area electroplated to form the antenna radiator.

14. The method for making an antenna as claimed in claim 9, wherein the organic filling substances comprise silicic acid and/or silicic acid derivatives.

15. The method for making an antenna as claimed in claim 9, wherein the ferrite core is adhered on the antenna radiator.
